(19) United States
(12) Patent Application Publication
(10) Pub. No.: US 2023/0301122 A1
(43) Pub. Date: Sep. 21, 2023

(54) PHOTOELECTRIC SURFACE

(71) Applicant: HAMAMATSU PHOTONICS K.K., Hamamatsu-shi, Shizuoka (JP)

(72) Inventors: Hiroyuki TAKETOMI, Hamamatsu-shi, Shizuoka (JP); Ryotaro ISHIKAWA, Hamamatsu-shi, Shizuoka (JP); Motohiro SUYAMA, Hamamatsu-shi, Shizuoka (JP); Tomohiko HIRANO, Hamamatsu-shi, Shizuoka (JP)

(73) Assignee: HAMAMATSU PHOTONICS K.K., Hamamatsu-shi, Shizuoka (JP)

(21) Appl. No.: 18/009,862

(22) PCT Filed: Mar. 10, 2021
(86) PCT No.: PCT/JP2021/009595

§ 371 Date: Dec. 12, 2022

(30) Foreign Application Priority Data
Jun. 25, 2020 (JP) 2020-109503

(51) Int. Cl. H10K 30/82

(52) U.S. Cl. CPC H10K 30/82

(57) ABSTRACT

A photoelectric surface includes a window material, a photoelectric conversion layer provided with a light incidence surface and an electron emission surface, and a carbon layer provided on the electron emission surface.

### TECHNICAL FIELD

The present invention relates to a photoelectric surface.

### BACKGROUND ART

Patent Literature 1 discloses a technology for generating photoelectrons by receiving ultraviolet rays. A photoelectron emitting material disclosed in Patent Literature 1 includes a base material that transmits ultraviolet rays, and a substance that emits photoelectrons and is provided on the base material. Materials including a metal (for example, platinum) are exemplified as some substances that emit photoelectrons.

### CITATION LIST

### Patent Literature

[Patent Literature 1] Japanese Unexamined Patent Publication No. 114-171062

### SUMMARY OF INVENTION

### Technical Problem

A device using a photoelectric surface, particularly a device using a photoelectric surface as an electron source, uses a photoelectric surface provided with a photoelectric conversion layer in some cases. The photoelectric conversion layer is affected less when exposed to the atmosphere. Further, the photoelectric conversion layer uses a material including a metal. When the device provided with the photoelectric conversion layer starts to operate, a predetermined standby time is provided in some cases. In some cases, the standby time includes a time required for emission of the photoelectrons from the photoelectric surface to satisfy a predetermined condition. The standby time affects operating efficiency of the device. In a photoelectric surface having a predetermined photoelectron emission property, the time required for the emission of the photoelectrons from the photoelectric surface to satisfy a predetermined condition can be set to be substantially constant. As a result, it becomes possible to efficiently operate the device using the photoelectric surface.

The present invention provides a photoelectric surface with a predetermined photoelectron emission property.

### Solution to Problem

A photoelectric surface, which is an aspect of the present invention, includes: a base material having one surface and the other surface opposite to the one surface; a photoelectric conversion layer provided on a side of the one surface, having a light incidence surface and an electron emission surface, and made of a material including a metal; and a carbon layer provided on a side of the electron emission surface.

The photoelectric surface includes the photoelectric conversion layer made of a material including a metal. Presence or absence of carbon atoms in the electron emission surface of the photoelectric surface affects a time required for emission of the photoelectrons from such a photoelectric surface to satisfy a predetermined condition. The photoelectric surface, which is the aspect of the present invention, includes the carbon layer provided on the electron emission surface. Therefore, it is possible to make the time required for the emission of photoelectrons to satisfy a predetermined condition from a start of the emission of the photoelectrons substantially constant. As a result, a photoelectric surface having a predetermined photoelectron emission property can be obtained.

In the photoelectric surface of the aspect, the material may include any one of platinum, copper, and gold. According to this configuration, the photoelectrons can be suitably generated for light in an ultraviolet region, for example.

In the photoelectric surface of the aspect, the carbon layer may include any one of graphene, amorphous carbon, and diamond-like carbon. According to this configuration, the emission of the photoelectrons from the electron emission surface can be suitably normalized.

In the photoelectric surface of the aspect, the base material may be formed of quartz. The photoelectric conversion layer may be formed of platinum. The electron emission surface may be a (111) plane. The carbon layer may be formed of a single layer of graphene. According to these configurations, a photoelectric surface having a predetermined photoelectron emission property can be more reliably obtained.

### Advantageous Effects of Invention

According to the present invention, a photoelectric surface with a predetermined photoelectron emission property is provided.

### BRIEF DESCRIPTION OF DRAWINGS

FIG. 1 is a diagram showing a configuration of a photoelectric surface according to an embodiment.

FIG. 2 is a schematic graph for explaining a change in sensitivity over time.

FIG. 3 is a table showing conditions and results of Experimental Examples 1, 2, 3 and 4.

FIG. 4 is a graph showing an example of a change in sensitivity over time.

FIG. 5 is a table summarizing evaluation results of work functions.

FIG. 6 is a graph showing another example of a change in sensitivity over time.

### DESCRIPTION OF EMBODIMENTS

Hereinafter, an embodiment for carrying out the present invention will be described in detail with reference to the accompanying drawings. In the description of the drawings, the same elements will be designated by the same reference signs, and duplicate description will be omitted.

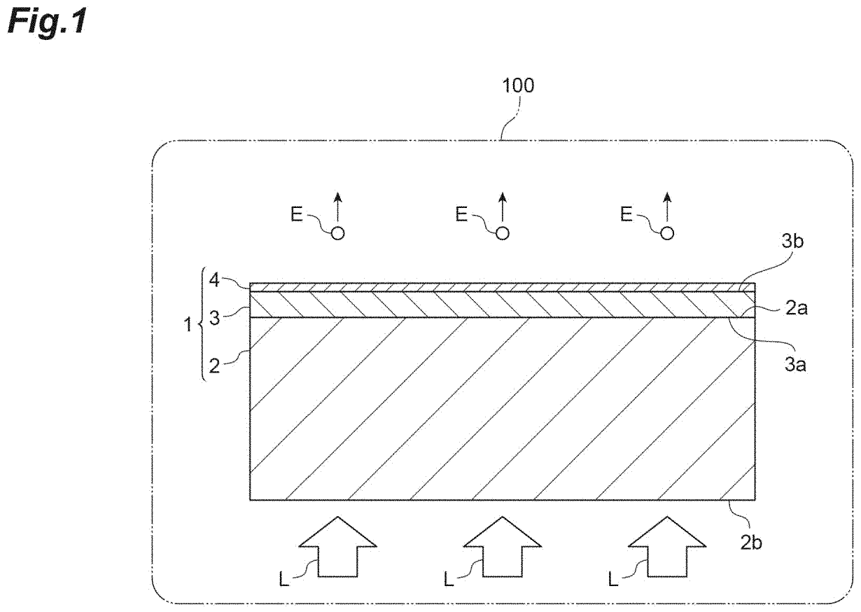

As shown in FIG. 1, a photoelectric surface 1 has a laminated structure. The photoelectric surface 1 includes a window material (a base material) 2, a photoelectric conversion layer 3, and a carbon layer 4. Light L that is incident on the window material 2 passes through the window material 2 and then reaches the photoelectric conversion layer 3. The photoelectric conversion layer 3 that has received the light L emits photoelectrons E. The photoelectric surface 1 is a transmissive photoelectric surface.

The window material 2 is a substrate of the photoelectric surface 1. The window material 2 has a window material main surface (one surface) 2a and a window material back surface (the other surface) 2b opposite to the window material main surface 2a. The photoelectric conversion layer 3 is formed on the window material main surface 2a. The window material back surface 2b is irradiated with the light L. The window material 2 has excellent light transmittance for light in a band targeted by the photoelectric surface 1. Accordingly, the window material 2 is made of a material that can transmit the light L. For example, in a case where a wavelength of the light L is in an ultraviolet region, for example, quartz (SiO₂) may be used as a material forming the window material 2. As the material forming the window material 2, calcium fluoride, magnesium fluoride, or sapphire may be used.

The photoelectric conversion layer 3 emits the photoelectrons E as a result of having received the light L. The photoelectric conversion layer 3 is formed on the window material main surface 2a. The photoelectric conversion layer 3 has a light incidence surface 3a in contact with the window material main surface 2a and an electron emission surface 3b. The light incidence surface 3a receives the light L from the window material 2. The electron emission surface 3b emits the photoelectrons E. The photoelectric conversion layer 3 is made of a material including a metal. For example, the photoelectric conversion layer 3 may be made of platinum (Pt). In a case where platinum is used as a material forming the photoelectric conversion layer 3, a crystal plane of the electron emission surface 3b is a (111) plane or a (100) plane. A thickness of the photoelectric conversion layer 3 using platinum is, for example, 6 nm or more and 7 nm or less. As another material forming the photoelectric conversion layer 3, a material capable of receiving the light L and emitting the photoelectrons E may be adopted. Examples of the other material forming the photoelectric conversion layer 3 include copper (Cu), gold (Au), or the like.

The carbon layer 4 is formed on the electron emission surface 3b. The carbon layer 4 changes a work function of the electron emission surface 3b. Specifically, the carbon layer 4 lowers the work function of the electron emission surface 3b. The work function is generally the minimum value of energy required to extract a single electron from a crystal surface of a metal or semiconductor to the outside of the crystal surface. In the case of a metal, the work function is greatly affected by an electron density state on the crystal surface. In other words, the work function is greatly affected by a state of the crystal surface. The carbon layer 4 contains carbon as a constituent material. Examples of a specific constituent material of the carbon layer 4 include graphene, diamond-like carbon, or amorphous carbon. It is preferable that a thickness of the carbon layer 4 be thin. Accordingly, a single layer of graphene is more preferable as a constituent material of the carbon layer 4. For example, in a case where the single layer of graphene is used, a transfer process can be adopted. A thickness of the single layer of graphene formed by the transfer process corresponds to one atom.

As described above, several combinations of the window material 2, the photoelectric conversion layer 3, and the carbon layer 4 can be exemplified. For example, as the photoelectric surface 1, a laminated structure of the window material 2 made of quartz, the photoelectric conversion layer 3 made of platinum in which the electron emission surface 3b is the (111) plane, and a carbon layer 4 made of a single layer of graphene is exemplified.

When the photoelectric surface disposed inside a vacuum container is irradiated with the light from the back surface of the window material, the photoelectrons are emitted from the photoelectric surface using the photoelectric conversion layer made of the material including a metal. The state of emission of the photoelectrons is unlikely to satisfy a predetermined condition immediately after light irradiation begins. Normally, the photoelectron emission gradually approaches a state in which a predetermined condition is satisfied as the light irradiation continues.

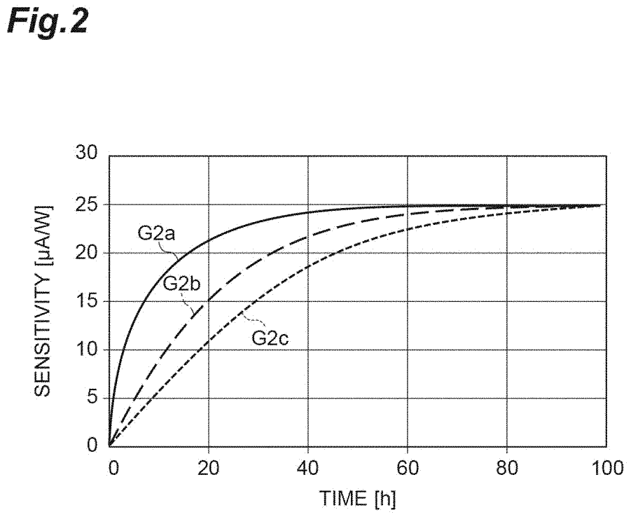

Furthermore, for example, even in a case where two photoelectric surfaces are manufactured under the same conditions, a time required for each to obtain a predetermined sensitivity may differ. In other words, a photoelectric surface having a predetermined photoelectron emission property may not be obtained. Graphs G2a, G2b, and G2c in FIG. 2 show changes in sensitivity over time of the photoelectric surface having no carbon layer and having the photoelectric conversion layer made of platinum. A horizontal axis of FIG. 2 indicates an elapsed time from the start of the light irradiation. A vertical axis in FIG. 2 indicates the sensitivity of the photoelectric surface. In each of the graphs G2a, G2b, and G2c, a time required for the sensitivity to reach 10 μA/W, for example, was checked. As a result, it was found that the time required for the sensitivity to reach 10 μA/W varies greatly from several hours to more than 10 hours. A time required for the emission of the photoelectrons to satisfy a predetermined condition cannot be used for an actual action to operate a device for its intended purpose. Accordingly, the time required for the emission of the photoelectrons to satisfy a predetermined condition is a time (a standby time) for waiting without operating the device for its intended purpose. If the time required for the emission of the photoelectrons to satisfy a predetermined condition varies, the standby time also varies. As a result, it becomes difficult to plan the operation of the device. On the other hand, if the time required for the emission of the photoelectrons to satisfy a predetermined condition can be kept within a predetermined range, the standby time can also be set to be a substantially constant time. Accordingly, it is also easy to plan the operation of the device.

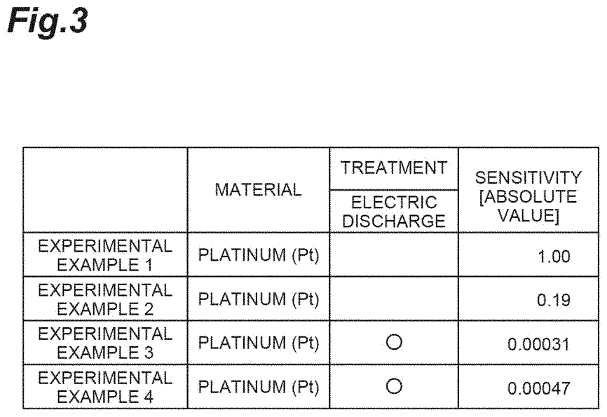

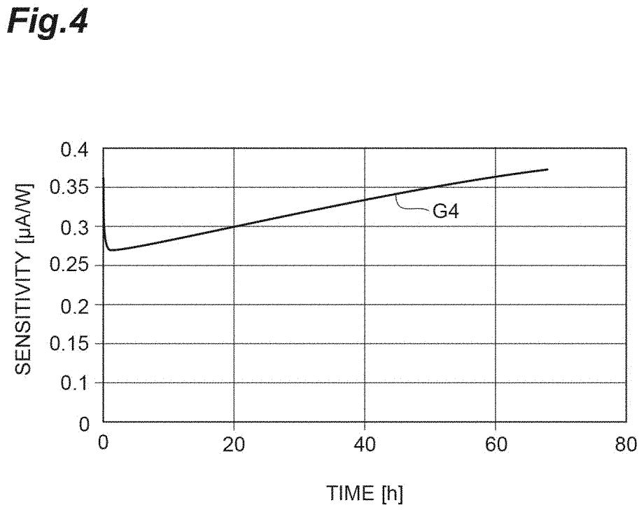

In order to examine factors of variation in the time required for the emission of the photoelectrons to satisfy a predetermined condition, the inventors performed Experimental Examples 1, 2, 3, and 4 shown in a table of FIG. 3. A graph G4 in FIG. 4 shows a result of Experimental Example 1 over time. An experimental parameter is the material forming the photoelectric conversion layer. In Experimental Example 1, platinum (Pt) was selected as the material forming the photoelectric conversion layer. Next, a plurality of photoelectric surfaces having the photoelectric conversion layer made of platinum were prepared. Next, the prepared photoelectric surfaces were disposed in a vacuum container. Then, the photoelectric surfaces were subjected to heat treatment. For Experimental Examples 3 and 4, electric discharge treatment was performed in addition to the heat treatment. The electric discharge treatment removes dirt adsorbed or accumulated on the electron emission surface of the photoelectric conversion layer. As a result, a front surface is kept clean. According to the electric discharge treatment, it is possible to make the front surface of the electron emission surface be the platinum itself. A wavelength of laser light with which the photoelectric conversion layer is irradiated is 266 nanometers. An output of the laser light is 11 mW. An extraction voltage for the photoelectrons is 15 V.

For example, in Experimental Examples 3 and 4, the photoelectric surface in which the photoelectric conversion layer for which platinum was adopted was subjected to the electric discharge treatment was used. In other words, the front surface of the photoelectric conversion layer was kept clean. As a result, it was found that the emission of the photoelectrons was hardly generated under the conditions of Experimental Examples 3 and 4 as can be understood from the values of the current and sensitivity. In other words, an effective sensitivity could not be checked under the conditions of Experimental Examples 3 and 4. This is because an original work function of platinum is 5 eV or more and 6 eV or less. However, energy of the applied laser light is 4.66 eV. In other words, the energy given by the laser light is lower than the work function of platinum forming the photoelectric conversion layer. Accordingly, no photoelectrons are emitted. On the other hand, in Experimental Examples 1 and 2, the photoelectric surface in which the photoelectric conversion layer for which platinum was adopted was not subjected to the electric discharge treatment was used. In other words, as compared with Experimental Examples 3 and 4, some contamination may occur on the front surface of the photoelectric conversion layer due to an influence of the atmosphere surrounding the photoelectric surface, the surrounding environment, and the like. The contamination may be caused by, for example, adsorption of gas molecules present in the surrounding environment and adhesion (deposition) of fine particles present in the surrounding environment. It was found that the emission of the photoelectrons was generated under the conditions of Experimental Examples 1 and 2 as can be understood from the values of the current and sensitivity. In other words, an effective sensitivity could be checked under the conditions of Experimental Examples 1 and 2. Energy of the applied laser light is 4.66 eV. The results of Experimental Examples 1 and 2 show that the work function of the photoelectric conversion layer changed. Specifically, the results of Experimental Examples 1 and 2 show that the work function of the photoelectric conversion layer was lowered. In other words, in the photoelectric conversion layer of Experimental Examples 1 and 2, some changes that would not have occurred if the front surface of the electron emission surface had been cleaned are predicted to have occurred. The work function is predicted to have changed from the original value of platinum to a value (less than 4.66 eV) at which the photoelectrons can be emitted with the energy of the laser light (4.66 eV) due to the changes that occurred on the front surface of the electron emission surface.

It is thought that atoms of a different type from atoms that constitute the photoelectric conversion layer adhere to a surface (the electron emission surface) of the photoelectric conversion layer from which the photoelectrons are emitted due to the influence of the atmosphere surrounding the photoelectric surface or the like unless the surface is actively cleaned. It was determined that the work function of the photoelectric conversion layer was changed by the atoms adhering to the electron emission surface. As a result of extensive studies, the inventors have found that adhesion of carbon to a surface (the electron emission surface) of the photoelectric conversion layer from which the photoelectrons are emitted changes the work function of the photoelectric conversion layer. Therefore, the inventors came to the conclusion that, by forming the carbon layer on the electron emission surface of the photoelectric conversion layer in advance, it is possible to keep the time required for the emission of the photoelectrons to satisfy a predetermined condition constant.

More specifically, the inventors have found that a state of the carbon layer formed on the electron emission surface of the photoelectric surface affects the time required for the emission of the photoelectrons from the photoelectric surface to satisfy a predetermined condition. The inventors considered that the emission of the photoelectrons is normalized when the state of the carbon layer is stabilized. Therefore, the inventors determined that, by forming the carbon layer under a predetermined condition in advance, it is possible to make the time from the start of the emission of the photoelectrons to the stabilization of the carbon layer nearly constant.

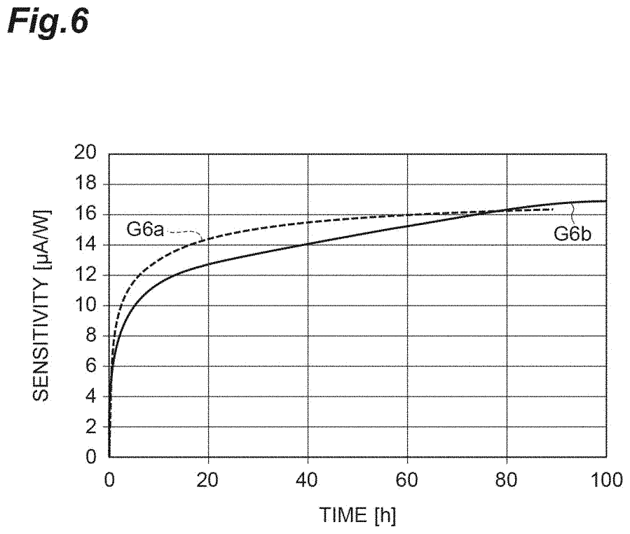

Graphs G6a and G6b in FIG. 6 show that, according to the photoelectric surface 1 of the embodiment, it is possible to set the time required for the sensitivity to reach 10 μA/W, for example, between 4 hours and 8 hours. In other words, the time required for the emission of the photoelectrons E to satisfy a predetermined condition can be kept within a predetermined range.

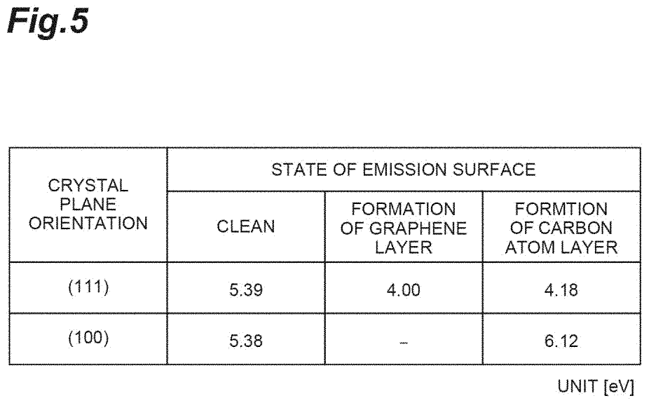

Furthermore, as shown in the table of FIG. 5, the inventors evaluated the work function of the photoelectric conversion layer 3 in different states of the electron emission surface 3b using first principle calculation. In the first principle calculation, the photoelectric conversion layer 3 was made of platinum. Then, in the first principle calculation, the work function of the photoelectric conversion layer 3 made of platinum in which the crystal plane is the (111) plane was evaluated. Furthermore, in the first principle calculation, the work function of the photoelectric conversion layer 3 made of platinum in which the crystal plane is the (100) plane was evaluated. The work function of the photoelectric conversion layer 3 in which the front surface of the electron emission surface 3b is clean was evaluated. Further, the work function of the photoelectric conversion layer 3 having a graphene layer formed on the electron emission surface 3b was evaluated. Furthermore, the work function of the photoelectric conversion layer 3 having a carbon atom layer formed on the electron emission surface 3b was evaluated.

As shown in FIG. 5, the work function of the photoelectric conversion layer 3 made of clean platinum in which the crystal plane is the (111) plane was 5.39 eV. On the other hand, the work function of the photoelectric conversion layer 3 having the carbon atom layer formed on a surface in which the crystal plane is the (111) plane was 4.18 eV. Furthermore, the work function of the photoelectric conversion layer 3 having the graphene layer formed on a surface in which the crystal plane is the (111) plane further decreased. Specifically, the work function of the photoelectric conversion layer 3 having the graphene layer formed on a surface in which the crystal plane is the (111) plane was 4.00 eV. These values are smaller than the energy (4.66 eV) of the above laser light. In other words, it was found that the state of the electron emission surface 3b of the photoelectric conversion layer 3 changed to a state in which photoelectrons E could be emitted. On the other hand, the work function of the photoelectric conversion layer 3 made of clean platinum in which the crystal plane is the (100) plane was 5.38 eV. On the other hand, the work function of the photoelectric conversion layer 3 having the carbon atom layer formed on a surface in which the crystal plane is the (100) plane was 6.12 eV. In other words, the work function increased. From these results, it was checked that, by forming a layer made of carbon on the electron emission surface 3b of the photoelectric conversion layer 3, it is possible to change the work function of the photoelectric conversion layer 3. In a case where the combination of the photoelectric conversion layer 3 made of platinum and the carbon layer 4 made of a single layer of graphene is adopted, it was found that graphene has an effect of changing the work function depending on the crystal plane of platinum. In other words, it was found that graphene lowers the work function depending on the crystal plane of platinum. In other words, from the viewpoint of use as the photoelectric surface 1, it was found that the (111) plane is more preferable than the (100) plane as the crystal plane of platinum.

Further, like the photoelectric surface 1 of the embodiment, the carbon layer 4 was formed to be thin intentionally on the front surface of the photoelectric conversion layer 3 made of platinum. As a result, it was possible to develop the sensitivity for the laser light in the ultraviolet region of 266 nm, which is a wavelength at which the photoelectric conversion layer 3 made of platinum originally cannot have the sensitivity.

The photoelectric surface 1 of the present invention is not limited to the above aspect. For example, in the above embodiment, the transmissive photoelectric surface was disclosed. The photoelectric surface may be of a reflective photoelectric surface. The window material (the base material) of the reflective photoelectric surface does not need to be light transmissive. Therefore, a material that does not transmit light such as a metal material may be used for the reflective photoelectric surface. Furthermore, in the reflective photoelectric surface, the base material may be integrated with the photoelectric conversion layer 3 made of a material including a metal. Moreover, the photoelectric surface is not limited to the configuration in which the window material 2 is brought into direct contact with the photoelectric conversion layer 3. Similarly, the photoelectric surface is not limited to the configuration in which the photoelectric conversion layer 3 is brought into direct contact with the carbon layer 4. For example, a layer for improving the characteristics of the photoelectric surface 1 may be added between the window material 2 and the photoelectric conversion layer 3. Similarly, a layer for improving the characteristics of the photoelectric surface 1 may be added between the photoelectric conversion layer 3 and the carbon layer 4. Moreover, the carbon layer 4 is not limited to a layer consisting of carbon atoms. The carbon layer 4 may include atoms other than carbon atoms. That is, the carbon layer 4 may be a carbon-containing layer. Further, the carbon layer 4 does not necessarily have to continuously cover the entire electron emission surface 3b of the photoelectric conversion layer 3. The carbon layer 4 may partially cover the electron emission surface 3b. Moreover, the carbon layer 4 may intermittently cover the electron emission surface 3b.

### REFERENCE SIGNS LIST

1 Photoelectric surface
2 Window material (base material)
3 Photoelectric conversion layer
4 Carbon layer

1: A photoelectric surface comprising:
a base material having one surface and the other surface opposite to the one surface;
a photoelectric conversion layer provided on a side of the one surface, having a light incidence surface and an electron emission surface, and made of a material including a metal; and
a carbon layer provided on a side of the electron emission surface.

2: The photoelectric surface of claim 1, wherein the material includes any one of platinum, copper, and gold.

3: The photoelectric surface according to claim 1, wherein the carbon layer includes any one of graphene, amorphous carbon, and diamond-like carbon.

4: The photoelectric surface according to claim 1,
wherein the base material is formed of quartz,
wherein the photoelectric conversion layer is formed of platinum,
wherein the electron emission surface is a (111) plane, and
wherein the carbon layer is formed of a single layer of graphene.
